(19) United States
(12) Patent Application Publication
(10) Pub. No.: US 2019/0207170 A1
(43) Pub. Date: Jul. 4, 2019

(54) TRANSPORT TOOL AND METHOD FOR MANUFACTURING ORGANIC ELECTROLUMINESCENT DISPLAY DEVICE USING SAID TRANSPORT TOOL

(71) Applicant: Sharp Kabushiki Kaisha, Sakai City, Osaka (JP)

(72) Inventors: Katsuhiro YAMAGUCHI, Sakai City (JP); Tadashi NISHIOKA, Sakai City (JP); Yuhji TANIGUCHI, Sakai City (JP)

(21) Appl. No.: 16/329,781

(22) PCT Filed: Aug. 30, 2017
(86) PCT No.: PCT/JP2017/031272

§ 371 Date: Mar. 1, 2019

(30) Foreign Application Priority Data
Sep. 5, 2016 (JP) 2016-172477

(51) Int. Cl. H01L 51/56; H01L 51/00; H05K 13/04

(52) U.S. Cl. CPC H01L 51/56; H05K 13/04; H01L 51/0097; H01L 51/003

(57) ABSTRACT

Disclosed is a panel transport tool including a plate member and an adhesive layer provided on the plate member and allowing a transported panel to be attached to and detached from the adhesive layer. The plate member includes a high floor portion holding the transported panel on a surface of the plate member via the adhesive layer, and a low floor portion having a surface below the surface of the high floor portion.

### TECHNICAL FIELD

The present invention relates to a transport tool and a method of manufacturing an organic EL display device using such a transport tool.

### BACKGROUND ART

In recent years, self-luminous organic electroluminescent (EL) display devices including organic EL elements have received attention in place of liquid crystal display devices.

For example, Patent Document 1 relates to a manufacturing method of an organic EL display device using a transport tool having an adhesive sheet, the method including an adhesive step, a separation step, and a peeling step, and discloses, in the peeling step, removing a foreign substance that has adhered to the adhesive sheet by peeling off the adhesive sheet from an element substrate.

### CITATION LIST

### Patent Document

Patent Document 1: Japanese Unexamined Patent Publication No. 2014-132523

### SUMMARY OF THE INVENTION

### Technical Problem

Among organic EL display devices, a proposed organic EL display device includes an organic EL display panel including a resin substrate as a base substrate in place of a conventionally used glass substrate. Here, since an organic EL display panel manufactured using a resin substrate is thin (e.g., with a thickness of approximately 50 μm to 200 μm) and flexible, it is difficult to keep the entire panel flat without floating on a stage, when, e.g., an electronic component is mounted on an end of the panel. Specifically, in an air adsorption type stage having an adsorption hole with a relatively large diameter (e.g., approximately 0.6 mm to 1.2 mm), it is possible to adsorb and hold the entire panel. However, the organic EL element formed inside the panel may be broken due to a local suction force by the adsorption hole. In a porous air adsorption type stage having an adsorption hole with a relatively small diameter, the organic EL element formed in the panel is hard to be broken. However, it is difficult to adsorb and hold the entire panel due to the elasticity of the entire panel.

It is an object of the present invention to keep an entire panel flat when an electronic component is mounted on an end of the panel.

### Solution to the Problem

In order to achieve the above object, a transport tool according to the present invention includes a plate member; and an adhesive layer provided on the plate member and allows a transported panel to be attached to and detached from the adhesive layer, wherein the plate member includes a high floor portion holding the transported panel on a surface of the plate member via the adhesive layer, and a low floor portion having a surface below a surface of the high floor portion.

### Advantages of the Invention

According to the present invention, the plate member includes the high floor portion holding the transported panel on the surface via the adhesive layer and the low floor portion having a surface below the surface of the high floor portion. This allows for keeping the entire panel flat when the electronic component is mounted on the end of the panel.

### BRIEF DESCRIPTION OF THE DRAWINGS

FIG. 1 is a perspective view of a transport tool according to a first embodiment of the present invention.

FIG. 2 is a cross-sectional view of the transport tool taken along line II-II of FIG. 1.

FIG. 3 is a perspective view showing a state in which a transported panel is placed on the transport tool according to the first embodiment of the present invention.

FIG. 4 is a perspective view showing a state in which the transported panel, on which an electronic component is mounted, is placed on the transport tool according to the first embodiment of the present invention.

FIG. 5 is a cross-sectional view taken along line V-V of FIG. 4, the view showing the state in which the transported panel, on which the electronic component is mounted, is placed on the transport tool.

FIG. 6 is a cross-sectional view showing a mounting step of a manufacturing method using the transport tool according to the first embodiment of the present invention.

FIG. 7 is a cross-sectional view showing a peeling step of the manufacturing method using the transport tool according to the first embodiment of the present invention.

FIG. 8 is a perspective view showing a state in which transport tools according to a second embodiment of the present invention are stacked.

FIG. 9 is a cross-sectional view taken along line IX-IX of FIG. 8, the view showing the state in which the transport tools are stacked.

FIG. 10 is a perspective view of a transport tool according to a third embodiment of the present invention.

FIG. 11 is a cross-sectional view taken along line XI-XI of FIG. 10, the view showing a step of manually peeling off the transported panel using a through hole provided to the transport tool.

FIG. 12 is a cross-sectional view taken along line XII-XII of FIG. 10, the view showing a step of mounting the electronic component on the transported panel using an elongated hole provided to the transport tool.

FIG. 13 is a cross-sectional view showing a mounting step of a manufacturing method according to a comparative example.

FIG. 14 is a cross-sectional view showing a peeling step of a manufacturing method according to a comparative example.

### DESCRIPTION OF EMBODIMENTS

Embodiments of the present invention will now be described in detail with reference to the drawings. Note that the present invention is not limited to the following embodiments.

### First Embodiment

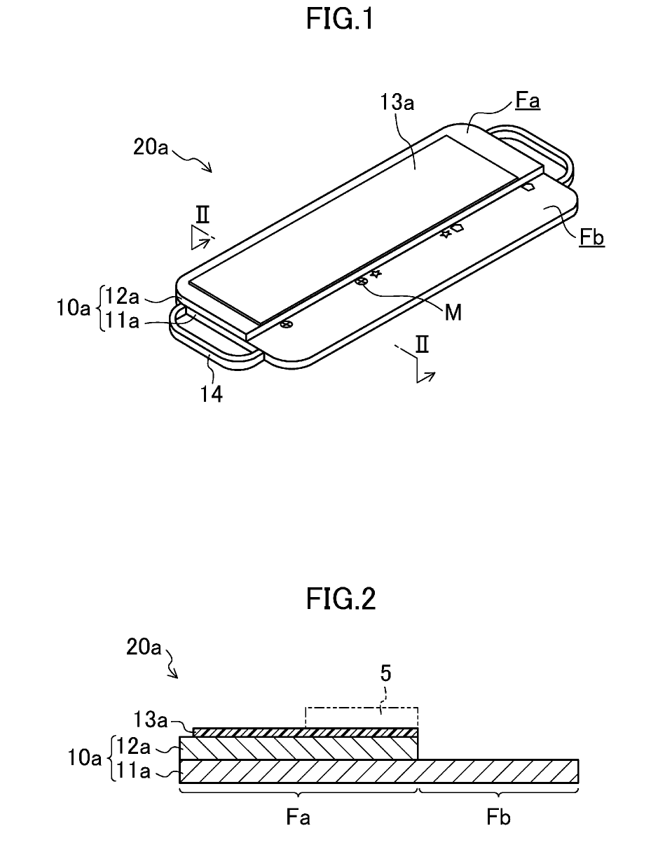

FIGS. 1 to 7 show a transport tool and a method of manufacturing an organic EL display device using the transport tool according to a first embodiment of the present invention. Here, FIG. 1 is a perspective view of a panel transport tool 20a of this embodiment. FIG. 2 is a cross-sectional view of the panel transport tool 20a taken along line II-II of FIG. 1.

First, an organic EL display device 9 to be manufactured using the panel transport tool 20a will be described.

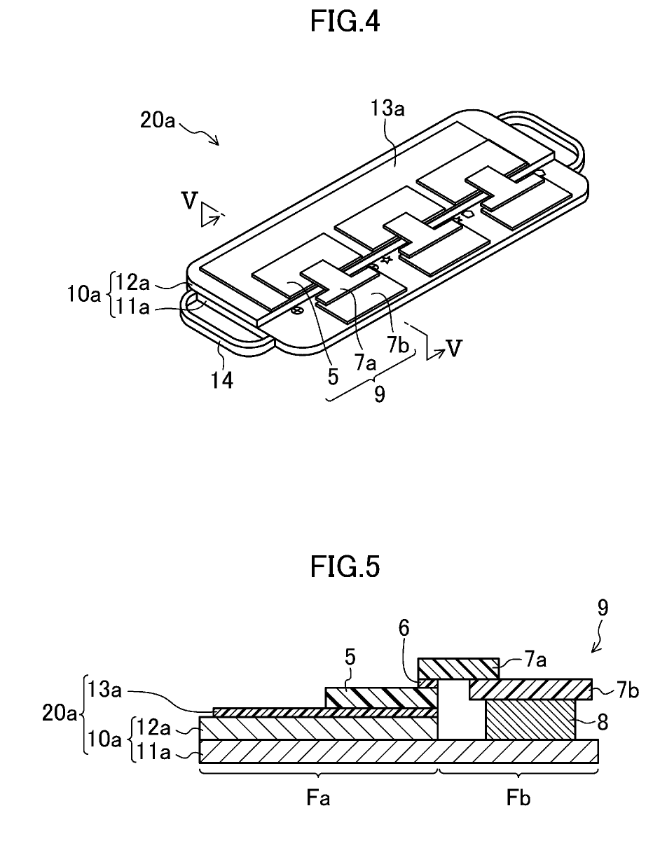

As shown in FIGS. 4 and 5, which will be described later, the organic EL display device 9 includes an organic EL display panel 5 serving as a transported panel and displaying an image, a first flexible printed circuit (FPC) 7a mounted at an end of the organic EL display panel 5, a second FPC 7b mounted at an end of the first FPC 7a, and an electronic component 8 mounted at a back surface of the second FPC 7b. This embodiment exemplifies the configuration in which the electronic component 8 is mounted on the back surface of the second FPC 7b. The electronic component may be mounted on the front surface of the second FPC 7b or both of the front and back surfaces of the second FPC 7b.

The organic EL display panel 5 includes an element substrate on which, e.g., an organic EL element is formed, a sealing substrate facing the element substrate, and a resin-filled layer provided between the element substrate and the sealing substrate. Here, in the organic EL display panel 5, a terminal region is provided at an end of the element substrate. Furthermore, in the organic EL display panel 5, a base substrate of the element substrate and a base substrate of the sealing substrate are made of, e.g., a polyimide resin, and have a thickness of approximately 50 μm to 200 μm, so that they are flexible and elastic.

As shown in FIG. 5, one end of the first FPC 7a is thermocompression-bonded to the terminal region of the organic EL display panel 5 via an anisotropic conductive film (ACF) 6. Furthermore, as shown in FIG. 5, the other end of the first FPC 7a is thermocompression-bonded to one end of the second FPC 7b via an ACF (not shown).

The electronic component 8 is, for example, an integrated circuit (IC) chip constituting, e.g., a drive circuit, and is thermocompression-bonded to the back surface of the second FPC 7b via an ACF (not shown), as shown in FIG. 5.

Next, the panel transport tool 20a will be described.

As shown in FIGS. 1 and 2, the panel transport tool 20a includes a plate member 10a substantially rectangular shaped with corners formed in an R shape in plan view, an adhesive layer 13a provided on the plate member 10a, and a pair of grip portions 14 respectively attached to the ends of the plate member 10a along a pair of short sides of the plate member 10a.

As shown in FIGS. 1 and 2, the plate member 10a includes a lower member 11a substantially rectangular shaped with corners formed in an R shape in plan view, and an upper member 12a stacked on the lower member 11a and substantially rectangular shaped with two corners formed in an R shape in plan view. The plate member 10a has a thickness of approximately 5 mm to 15 mm Note that, this embodiment exemplifies the plate member 10a including the upper member 12a provided on the lower member 11a. Alternatively, the lower member 11a and the upper member 12a may be integrated together.

As shown in FIGS. 1 and 2, the upper member 12a is attached onto the lower member 11a with an adhesive such as an epoxy resin, and forms an upper layer portion of a high floor portion Fa which holds the organic EL display panel 5 on a surface of the high floor portion Fa via the adhesive layer 13a. Note that the lower portion of the high floor portion Fa is configured as the lower member 11a. Furthermore, a portion, of the lower member 11a, protruding outward from the upper member 12a constitutes a low floor portion Fb having a surface below the surface of the high floor portion Fa. Here, a difference in height between the surfaces of the high floor portion Fa and the low floor portion Fb, i.e., a difference in level on the plate member 10a, is approximately 1 mm so that the organic EL display panel 5 held on the surface of the high floor portion Fa does not float due to the contact between the surface of the low floor portion Fb and the electronic component 9. Furthermore, the lower member 11a and the upper member 12a are made of, e.g., a magnesium alloy, an aluminum alloy, or an epoxy resin impregnated glass fiber. Further, as shown in FIG. 1, a mark M having a predetermined shape (e.g., a round cross shape, a star shape, and a pentagonal shape) for image recognition is provided on the surface of the low floor portion Fb.

The adhesive layer 13a has low adhesiveness to allow the organic EL display panel 5 to be attached to and detached from the adhesive layer 13a, so that the organic EL display panel 5 can be peeled off with a force of approximately several tens of mN. Here, as the adhesive layer 13a, for example, a suitable adhesive is an adhesive tape of TACSIL F20 manufactured by E-Globaledge Corporation (with a mould releasing film removed from the front and back surfaces of the tape).

The grip portion 14 is formed in a U-shape or a C-shape, and is made of a heat-resistant resin such as a polycarbonate resin.

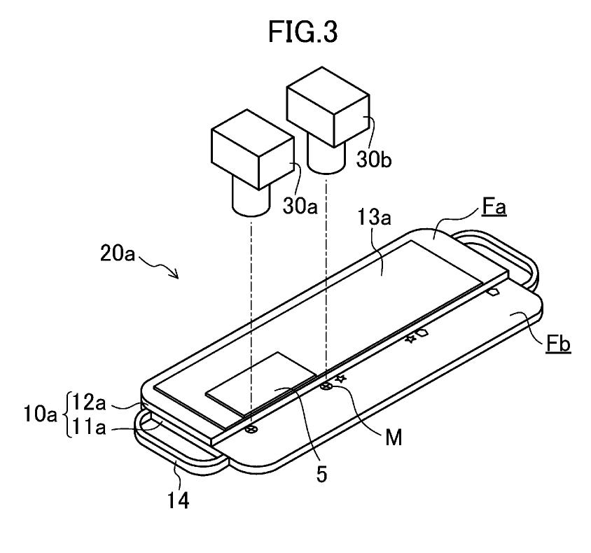

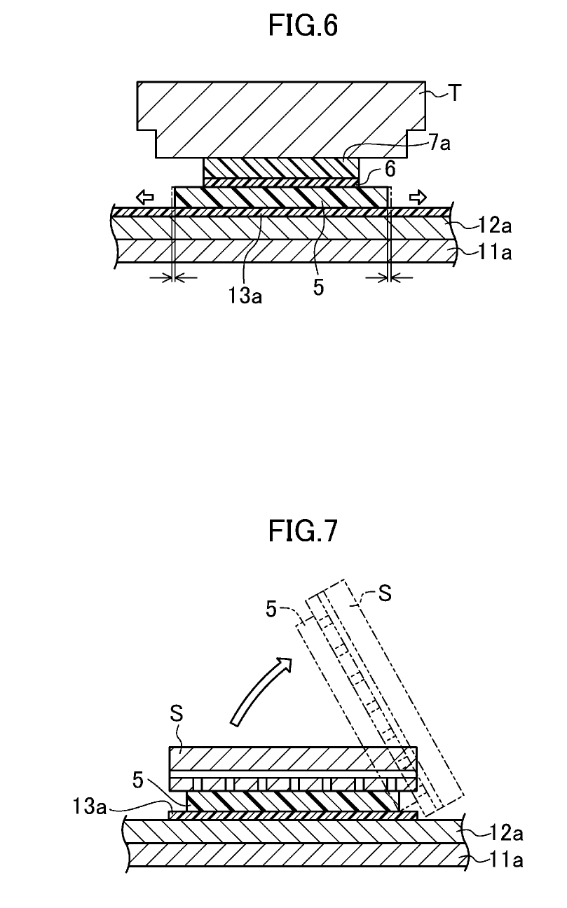

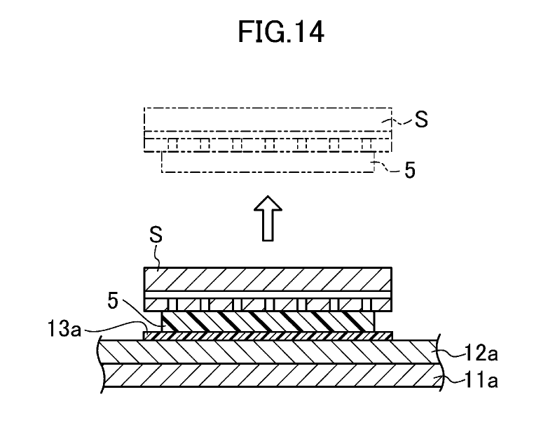

Next, a method of manufacturing the organic EL display device 9 using the panel transport tool 20a will be described. Here, FIG. 3 is a perspective view showing a state in which the organic EL display panel 5 is placed on the panel transport tool 20a. FIG. 4 is a perspective view showing a state in which the organic EL display panel 5, on which the electronic component 8 is mounted, is placed on the panel transport tool 20a. FIG. 5 is a cross-sectional view taken along line V-V of FIG. 4, the view showing the state in which the organic EL display panel 5, on which an electronic component 8 is mounted, is placed on the panel transport tool 20a. Furthermore, FIGS. 6 and 7 are cross-sectional views respectively showing a mounting step and a peeling step of a method of manufacturing the organic EL display device 9 using the panel transport tool 20a. Furthermore, FIGS. 13 and 14 are cross-sectional views respectively showing a mounting step and a peeling step of a manufacturing method according to comparative examples. Note that the method of manufacturing the organic EL display device 9 according to this embodiment includes a placing step, the mounting step, and the peeling step.

<Placing Step>

First, as shown in FIG. 3, after the mark M on the low floor portion Fb of the panel transport tool 20a is detected by charge coupled device (CCD) cameras 30a and 30b, three organic EL display panels 5 are placed on the surface of the adhesive layer 13a of the high floor portion Fa of the panel transport tool 20a in a line (see FIG. 4). In this embodiment, the method of detecting the mark M on the panel transport tool 20a has been exemplified. Not only the mark M but also the height of the panel transport tool 20a or the height of the organic EL display panels 5 placed on the panel transport tool 20a may be detected to reflect, e.g., the variation in the thickness of the panel transport tool 20a, and the deflection, thereby improving the accuracy of subsequent steps.

Subsequently, three mounting components are prepared in which the first FPC 7a and the second FPC 7b are connected to each other, the electronic component 8 is mounted on the back surface of the second FPC 7b, and the ACF 6 is attached to the back surface of the first FPC 7a. Three electronic components 8 of the mounting components are placed on the surface of the low floor portion Fb of the panel transport tool 20a in a line (see FIGS. 4 and 5).

<Mounting Step>

After the placing step, as shown in FIG. 6, the first FPC 7a is press-bonded to the terminal region of the organic EL display panel 5 placed on the panel transport tool 20a using a connection tool T, so that the electronic component 8 is mounted on the organic EL display panel 5. Here, in the manufacturing method using the panel transport tool 20a, as shown in FIG. 6, the adhesive layer 13a is provided between the plate member 10a and the organic EL display panel 5. Therefore, thermal expansion of the organic EL display panel 5 caused by the connection tool T is reduced, so that the degree of elongation of the organic EL display panel 5 is reduced and the connection accuracy can be improved. In contrast, in the manufacturing method of the comparative example, as shown in FIG. 13, no adhesive layer 13a is disposed between the plate member and the organic EL display panel 5. Therefore, thermal expansion of the organic EL display panel 5 caused by the connection tool T is less likely to be reduced, and the degree of elongation of the organic EL display panel 5 becomes large.

<Peeling Step>

After the mounting step, as shown in FIG. 7, the surface of the organic EL display panel 5, placed on the panel transport tool 20a, that has been adsorbed onto an adsorption stage S of an air adsorption type is swung from a horizontal state to an inclined state. As a result, the organic EL display panel 5 is peeled off from the adhesive layer 13a from one end side (the left side on the drawing) of the organic EL display panel 5 toward the other end side (the right side on the drawing). Here, in the manufacturing method for swinging the adsorption stage S, as shown in FIG. 7, the force for peeling off the organic EL display panel 5 can be reduced, so that the organic EL display panel 5 can be easily peeled off from the adhesive layer 13a. On the other hand, in the manufacturing method of the comparative example, as shown in FIG. 14, since the adsorption stage S is vertically pulled up, a force for peeling the organic EL display panel 5 inevitably increases. In addition, in FIG. 7, the adsorption stage S to be swung may be deformed into an arc shape in a side view when the organic EL display panel 5 is peeled off from the adhesive layer 13a since a force for peeling off the organic EL display panel 5 may be small.

As described above, it is possible to manufacture the organic EL display device 9 in which the electronic component 8 is mounted on the organic EL display panel 5.

As described above, the panel transport tool 20a and the method of manufacturing the organic EL display device 9 using the same according to this embodiment allow for obtaining the following advantages.

(1) The plate member 10a includes the high floor portion Fa that holds the organic EL display panel 5 on the surface via the adhesive layer 13a, and the low floor portion Fb having a surface below the surface of the high floor portion Fa. Accordingly, with the organic EL display panel 5 placed on the surface of the high floor portion Fa, the electronic component 8 to be mounted on the organic EL display panel 5 can be placed on the surface of the low floor portion Fb. Thus, since the organic EL display panel 5 held on the surface of the high floor portion Fa is hard to float in the terminal region on which the electronic component 8 is mounted. Thus, when the electronic component 8 is mounted on the end of the panel, the entire panel can be held flat.

(2) Since the mark M for image recognition is provided on the surface of the plate member 10a, the panel transport tool 20a can be reliably recognized in each manufacturing apparatus.

(3) Since the grip portion 14 is provided at an end of the plate member 10a, the transport with the panel transport tool 20a can be performed not only by a mechanical operation but also by a manual operation.

(4) Since the plate member 10a is made of a magnesium alloy, an aluminum alloy, or an epoxy resin impregnated glass fiber, the panel transport tool 20a to be implemented is light and stiff.

(5) In the mounting step, the electronic component 8 is mounted on the organic EL display panel 5 by thermocompression bonding the first FPC 7a to the organic EL display panel 5 placed on the surface of the high floor portion Fa via the adhesive layer 13a. This can reduce thermal expansion of the organic EL display panel 5 caused by the connection tool T. Thus, since the degree of elongation of the organic EL display panel 5 is reduced, it is possible to improve the accuracy of the connection of the first FPC 7a with respect to the organic EL display panel 5.

(6) In the placing step, three organic EL display panels 5 are placed in a line on the surface of the high floor portion Fa, and three electronic components 8 each associated with one of the three organic EL display panels 5 are placed in a line on the surface of the low floor portion Fb. This makes it possible to simultaneously process a plurality of organic EL display panels 5.

(7) In the peeling step, the surface of the organic EL display panel 5 on which the electronic component 8 is mounted is adsorbed, and the organic EL display panel 5 is peeled off from the adhesive layer 13a from one end side of the organic EL display panel 5 toward the other end side. As a result, the force for peeling off the organic EL display panel 5 can be reduced, so that the organic EL display panel 5 can be easily peeled off from the adhesive layer 13a.

### Second Embodiment

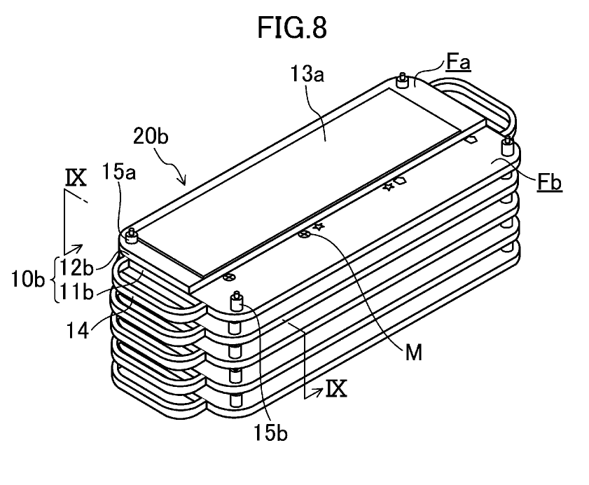

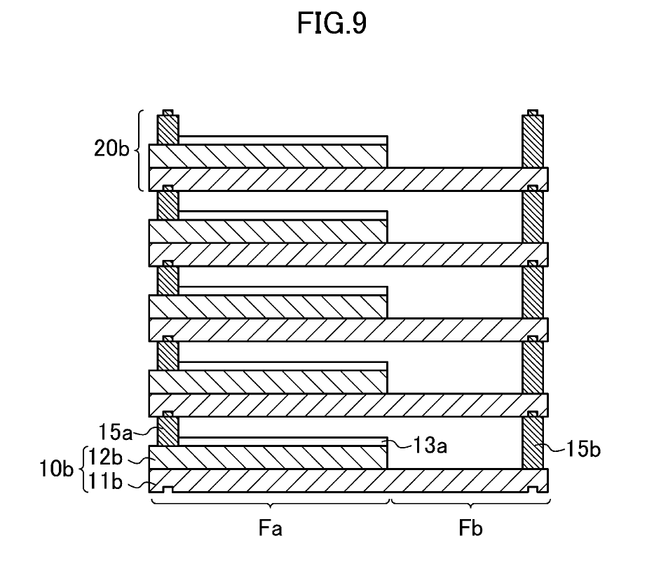

FIGS. 8 and 9 show a transport tool and a method of manufacturing an organic EL display device using the transport tool according to a second embodiment of the present invention. Here, FIG. 8 is a perspective view showing a state in which panel transport tools 20b of this embodiment are stacked on each other. FIG. 9 is a cross-sectional view taken along line IX-IX of FIG. 8, the view showing the state in which the panel transport tools 20b are stacked on each other. In the embodiments below, components equivalent to those shown in FIGS. 1 to 7 are denoted by the same reference characters, and the detailed explanation thereof will be omitted.

In the first embodiment, the exemplified panel transport tool 20a is not stackable. In this embodiment, a panel transport tool 20b to be exemplified is stackable.

As shown in FIGS. 8 and 9, the panel transport tool 20b includes a plate member 10b substantially rectangular shaped with corners formed in an R shape in plan view, an adhesive layer 13a provided on the plate member 10b, and a pair of grip portions 14 respectively attached to the ends of the plate member 10b along a pair of short sides of the plate member 10b.

As shown in FIGS. 8 and 9, the plate member 10b includes a lower member 11b substantially rectangular shaped with corners formed in an R shape in plan view, and an upper member 12b provided on the lower member 11b and substantially rectangular shaped with corners formed in an R shape in plan view. The plate member 10b has a thickness of approximately 5 mm to 15 mm.

As shown in FIGS. 8 and 9, the upper member 12b is attached onto the lower member 11b with an adhesive such as an epoxy resin, and forms an upper layer portion of a high floor portion Fa which holds the organic EL display panel 5 on the surface on the surface of the plate member 10b via the adhesive layer 13a. As shown in FIGS. 8 and 9, a pair of columnar pins 15a is provided on the surface of the upper member 12b (the high floor portion Fa) with a relatively low height. Note that the lower portion of the high floor portion Fa is configured as the lower member 11b. Furthermore, a portion, of the lower member 11b, protruding outward from the upper member 12b constitutes a low floor portion Fb having a surface below the surface of the high floor portion Fa. As shown in FIGS. 8 and 9, a pair of columnar pins 15b is provided on the surface of the portion (the low floor portion Fb), of the lower member 11b, protruding from the upper member 12b, the pins 15b having a relatively high height. Furthermore, the lower member 11b and the upper member 12b are made of, e.g., a magnesium alloy, an aluminum alloy, or an epoxy resin impregnated glass fiber. Furthermore, as shown in FIG. 8, the surface of the low floor portion Fb is provided with a mark M having a predetermined shape (e.g., a round cross shape, a star shape, and a pentagonal shape) which indicates a reference position at the time of positioning components. Furthermore, each of the pins 15a and 15b is formed of, e.g., a metal such as stainless steel or a heat-resistant resin to have a diameter of approximately 3 mm to 10 mm. As shown in FIGS. 8 and 9, each of the top portions of the pins 15a and 15b is raised, and a recessed portion is provided on the back surface of the lower member 11b so that the raised portion of each of the top portions is fitted into the recessed portion.

As shown in FIGS. 8 and 9, the plurality of panel transport tools 20b having the above configuration can be stacked on each other by fitting the raised portions of the top portions of the pins 15a and 15b of the panel transport tool 20b on the lower stage side into the corresponding recessed portions provided on the back surface of the lower member 11b of the panel transport tool 20b on the upper stage side. Note that the organic EL display panel 5 may be placed on the adhesive layer 13a of the high floor portion Fa of the panel transport tool 20b of each stage. Alternately, as shown in FIGS. 8 and 9, the organic EL display panel 5 does not have to be placed on the adhesive layer 13.

As described above, the panel transport tool 20b and the method of manufacturing the organic EL display device 9 using the same according to this embodiment allows for obtaining the following advantage in addition to the above mentioned (1) to (7).

(8) The plate member 10b is provided with the plurality of columnar pins 15a and 15b. As a result, the plurality of panel transport tools 20b are arranged so as to be stacked on each other, thereby saving the space and efficiently carrying the panel transport tool 20b, regardless of whether the organic EL display panel 5 is placed on the adhesive layer 13a of the high floor portion Fa of each panel transport tool 20b.

### Third Embodiment

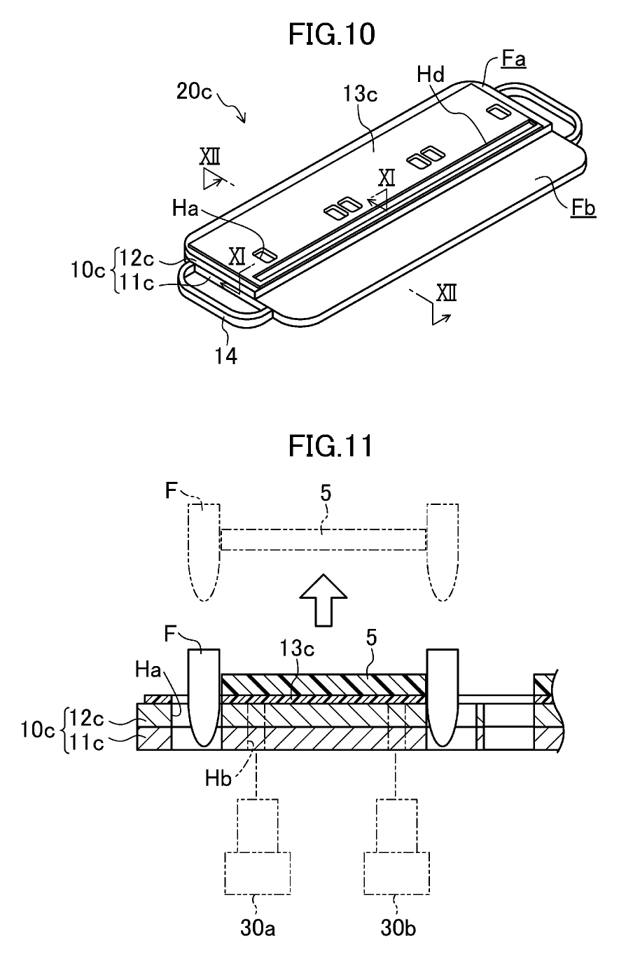

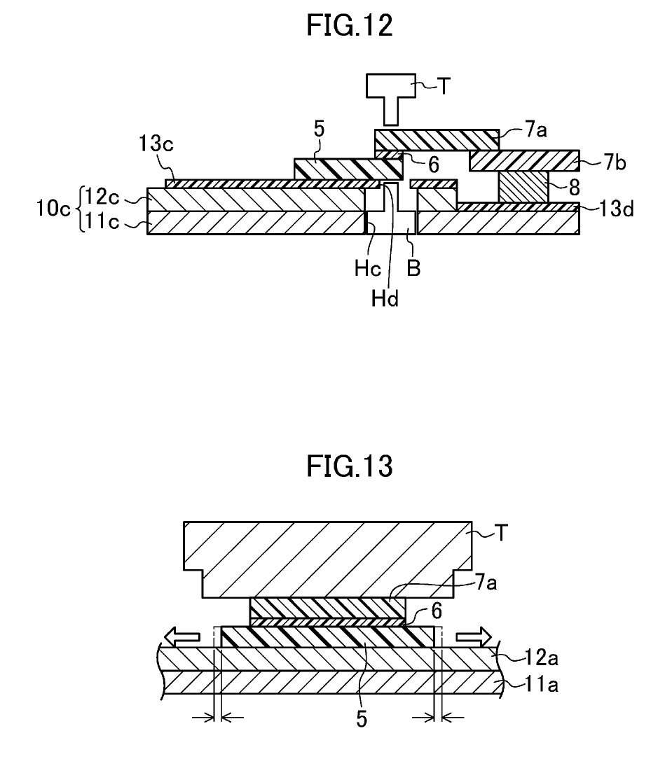

FIGS. 10 to 12 show a transport tool and a method of manufacturing an organic EL display device using the transport tool according to a third embodiment of the present invention. Here, FIG. 10 is a perspective view of a panel transport tool 20c of this embodiment. FIG. 11 is a cross-sectional view of the panel transport tool 20c taken along line XI-XI of FIG. 10, the view showing a step of manually peeling off the organic EL display panel 5 using a through hole Ha provided to the panel transport tool 20c. FIG. 12 is a cross-sectional view of the panel transport tool 20c taken along line XII-XII of FIG. 10, the view showing a step of mounting the electronic component 8 on the organic EL display panel 5 using elongated holes Hc and Hd provided to the panel transport tool 20c.

In the first and second embodiments, the exemplified panel transport tools 20a and 20b include the plate members 10a and 10b provided with no through hole. In this embodiment, the panel transport tool 20c to be exemplified includes the plate member 10c provided with through holes.

As shown in FIGS. 10 to 12, the panel transport tool 20c includes a plate member 10c substantially rectangular shaped with corners formed in an R shape in plan view, adhesive layers 13c and 13d provided on the plate member 10c, and a pair of grip portions 14 respectively attached to the ends of the plate member 10c along a pair of short sides of the plate member 10c.

As shown in FIGS. 10 to 12, the plate member 10c includes a lower member 11c substantially rectangular shaped with corners formed in an R shape in plan view, and an upper member 12c provided on the lower member 11c and substantially rectangular shaped with corners formed in an R shape in plan view. The plate member 10c has a thickness of approximately 3 mm to 5 mm.

As shown in FIGS. 10 to 12, the upper member 12c is attached onto the lower member 11c with an adhesive such as an epoxy resin, and forms an upper layer portion of a high floor portion Fa which holds the organic EL display panel 5 on the surface of the plate member 10c via the adhesive layer 13c. Note that the lower portion of the high floor portion Fa is configured as the lower member 11c. Furthermore, a portion, of the lower member 11c, protruding outward from the upper member 12c constitutes a low floor portion Fb having a surface below the surface of the high floor portion Fa. Furthermore, the lower member 11c and the upper member 12c are made of, e.g., a magnesium alloy, an aluminum alloy, or an epoxy resin impregnated glass fiber.

The adhesive layers 13c and 13d have low adhesiveness to allow the organic EL display panel 5 to be attached to and detached from the adhesive layers 13c and 13d, so that the organic EL display panel 5 can be peeled off with a force of approximately several tens of mN. Here, as the adhesive layers 13c and 13d, for example, a suitable adhesive is an adhesive tape of TACSIL F20 manufactured by E-Globaledge Corporation (with a mould releasing film removed from the front and back surfaces of the tape).

Here, as shown in FIGS. 10 and 11, a plurality of through holes Ha are provided in the high floor portion Fa of the plate member 10c so as to penetrate in the thickness direction. Furthermore, the adhesive layer 13c has a plurality of through holes Ha continuous with the plurality of through holes Ha of the plate member 10c, and penetrating in the thickness direction such that the adhesive layer 13c does not block the through holes Ha of the plate member 10c. Therefore, as shown in FIG. 11, the operator can peel off the organic EL display panel 5 from the adhesive layer 13c by inserting a finger F into the through holes Ha provided in the plate member 10c and the adhesive layer 13c, holding the end face of the organic EL display panel 5 with the finger F, and lifting up the organic EL display panel 5. In addition, a plurality of through holes Hb (see the dash-dot-dot line in FIG. 11) may be provided through the high floor portion Fa of the plate member 10c in the thickness direction in order to detect a mark formed on the organic EL display panel 5 using the CCD cameras 30a and 30b (see the dash-dot-dot line in FIG. 11).

As shown in FIG. 12, at an end along the long side of the high floor portion Fa, of the plate member 10c, near the low floor portion Fb, a first elongated hole Hc is provided. The first elongated hole Hc penetrates the plate member 10c in the thickness direction of the high floor portion Fa, and extends along the long side. Furthermore, as shown in FIGS. 10 and 12, a second elongated hole Hd is provided in the adhesive layer 13c so as to be concentric with the first elongated hole Hc. The second elongated hole Hd penetrates the adhesive layer 13c in the thickness direction, and extends along the long side of the high floor portion Fa near the low floor portion Fb. The second elongated hole Hd is smaller than the first elongated hole Hc. According to such a configuration, as shown in FIG. 12, the adhesive layer 13c is formed so as to have eaves-like portions at a portion overlapping with the first elongated hole Hc. Therefore, as shown in FIG. 12, when a backup unit B is provided at the first elongated hole Hc below the organic EL display panel 5, and the connection tool T is provided above the first FPC 7a, the terminal region of the organic EL display panel 5 is supported by the eaves-like portions of the adhesive layer 13c, thereby easily keeping the organic EL display panel 5 flat. Thereafter, the organic EL display panel 5, the ACF 6, and the first FPC 7a are sandwiched between the backup unit B and the connection tool T, so that the first FPC 7a can be pressure-bonded to the terminal region of the organic EL display panel 5.

As described above, the panel transport tool 20c and the method of manufacturing the organic EL display device 9 using the same according to this embodiment allow for obtaining the following advantages in addition to the above-mentioned (1), and (3) to (7).

(9) The high floor portion Fa is provided with the plurality of through holes Ha penetrating in the thickness direction, and the adhesive layer 13c is provided so as not to overlap with the plurality of through holes Ha. As a result, the organic EL display panel 5 can be manually peeled off from the adhesive layer 13c using the plurality of through holes Ha.

(10) At the end of the high floor portion Fa along the long side of the low floor portion Fb near the low floor portion Fb, the first elongated hole Hc is provided which penetrates in the thickness direction and extends along the long side. The adhesive layer 13c is provided with the second elongated hole Hd which is concentric with the first elongated hole Hc, penetrates in the thickness direction, extends along the long side, and is smaller than the first elongated hole Hc. Therefore, the organic EL display panel 5, the ACF 6, and the first FPC 7a are sandwiched between the backup unit B provided at the portion of the first elongated hole Hc located below the organic EL display panel 5 and the connection tool T provided above the first FPC 7a, such that the first FPC 7a can be pressure-bonded to the terminal region of the organic EL display panel 5. Here, the connection tool T at the time of pressure-bonding faces the backup unit B, not the plate member 10c. This can reduce the thickness of the plate member 10c, and the weight of the panel transport tool 20c. In addition, the plate member 10c does not have to have a flatness required for stably performing pressure-bonding, thereby reducing the cost of the panel transport tool 20c. Furthermore, the adhesive layer 13c has the eaves-like portions at the portion overlapping with the first elongated hole Hc. Therefore, the terminal region of the organic EL display panel 5 is supported by the eaves-like portion of the adhesive layer 13c, and thus the organic EL display panel 5 can be easily kept flat.

(11) The adhesive layer 13d is also provided on the lower member 11c constituting the low floor portion Fb. Hence, the panel transport tool 20c can adhesively hold not only the organic EL display panel 5 but also the electronic component 8. Accordingly, the panel transport tool 20c can be moved at high speed with the organic EL display panel 5 and the electronic component 8 placed on the panel transport tool 20c.

### Other Embodiments

In each of the above embodiments, the method of manufacturing the organic EL display device including the flexible organic EL display panel using the panel transport tools 20a to 20c has been exemplified. The present invention can also be applied to a method of manufacturing a liquid crystal display device including a flexible liquid crystal display panel.

In each of the above embodiments, the panel transport tools 20a to 20c have been exemplified. The present invention can also be applied to another panel transport tool in which the combinations of the constitutional elements of the exemplified panel transport tools 20a to 20c are changed in any given manners.

Each of the above embodiments exemplifies a manufacturing method in which a transport tool is used in the mounting step in the manufacturing process of the organic EL display device including the flexible organic EL display panel. The transport tool of the present invention can be applied to a manufacturing process such as an attachment of an optical sheet, such as a polarizing plate, or a resin coating.

### INDUSTRIAL APPLICABILITY

As can be seen from the foregoing description, the present invention is useful for manufacturing an organic EL display device including a flexible organic EL display panel.

### DESCRIPTION OF REFERENCE CHARACTERS

Fa High Floor Portion
Fb Low Floor Portion
Ha, Hb Through Hole
Hc First Elongated Hole
Hd Second Elongated Hole
M Mark
5 Organic EL Display Panel (Transported Panel)
7a First FPC (Flexible Wiring Board)
7b Second FPC (Flexible Wiring Board)
8 Electronic Component
10a to 10c Plate Member
13a, 13c Adhesive Sheet (Adhesive Layer)
14 Grip Portion
15a, 15b Pin
20a to 20c Panel Transport Tool

1. A transport tool comprising:
a plate member; and
an adhesive layer provided on the plate member and allows a transported panel to be attached to and detached from the adhesive layer, wherein
the plate member includes a high floor portion holding the transported panel on a surface of the plate member via the adhesive layer, and a low floor portion having a surface below a surface of the high floor portion.

2. The transport tool of claim 1, wherein
a mark for image recognition is provided on the surface of the plate member.

3. The transport tool of claim 1, wherein
a plurality of columnar pins are provided on the surface of the plate member.

4. The transport tool of claim 1, wherein
a grip portion is provided at an end of the plate member.

5. The transport tool of claim 1, wherein
the high floor portion is provided with a through hole penetrating through the high floor portion in a thickness direction of the high floor portion, and
the adhesive layer is provided so as not to block the through hole.

6. The transport tool of claim 1, wherein
the high floor portion is rectangular shaped in plan view,
the low floor portion is rectangular shaped in plan view so that a long side of the high floor portion and a long side of the low floor portion are adjacent to each other,
at an end along the long side, of the high floor portion, near the low floor portion, a first elongated hole is provided to penetrate in a thickness direction of the high floor portion, and to extend along the long side,
in the adhesive layer, a second elongated hole is provided so as to be concentric with the first elongated hole, the second elongated hole penetrating the adhesive layer in a thickness direction, extending along the long side, and being smaller than the first elongated hole, and
the adhesive layer has an eaves-like portion at a portion overlapping with the first elongated hole.

7. The transport tool of claim 1, wherein
the plate member is made of a magnesium alloy, an aluminum alloy, or an epoxy resin impregnated glass fiber.

8. A method of manufacturing an organic EL display device using the transport tool of claim 1, the method comprising:
placing an organic EL display panel on a surface of the high floor portion via the adhesive layer, and placing, on a surface of the low floor portion, an electronic component to which a flexible wiring substrate is connected; and
mounting the electronic component on the organic EL display panel placed on the surface of the high floor portion by thermocompression-bonding the flexible wiring substrate to the organic EL display panel.

9. The method of claim 8, wherein
the organic EL display panel includes a plurality of organic EL display panels, the electronic component includes a plurality of electronic components each associated with one of the organic EL display panels, and in the placing, the plurality of the organic EL display panels are placed on the surface of the high floor portion in a line, and the plurality of the electronic components are placed on the surface of the low floor portion in a line.

10. The method of claim 8, further comprising
adsorbing a surface of the organic EL display panel on which the electronic component is mounted, and peeling off the organic EL display panel from the adhesive layer from one end side of the organic EL display panel toward the other end side.
